(19) United States
(12) Patent Application Publication
(10) Pub. No.: US 2007/0058224 A1
(43) Pub. Date: Mar. 15, 2007

(54) Image processing apparatus and image processing method

(75) Inventors: Hiroyuki Kawamoto, Kanagawa (JP); Tomoyuki Yoshida, Tokyo (JP); Toshiya Hikita, Tokyo (JP); Takeharu Tone, Kanagawa (JP); Shuji Kimura, Kanagawa (JP); Atsushi Togami, Kanagawa (JP); Takumi Nozawa, Kanagawa (JP); Toshimi Yamamura, Kanagawa (JP); Akira Murakata, Tokyo (JP); Satoshi Ohkawa, Tokyo (JP); Manabu Komatsu, Tokyo (JP); Yasunobu Shirata, Tokyo (JP); Yukihiko Tamura, Kanagawa (JP)

Correspondence Address: HARNESS, DICKEY & PIERCE, P.L.C., P.O. BOX 8910, RESTON, VA, 20195, US

(73) Assignee: Ricoh Company, Limited

(21) Appl. No.: 11/516,525

(22) Filed: Sep. 7, 2006

(30) Foreign Application Priority Data
Sep. 13, 2005 (JP) 2005-266015

(51) Int. Cl. G03F 3/08

(52) U.S. Cl. 358/518; 358/1.9

(57) ABSTRACT

An image processing apparatus includes an image reading unit that reads an image of a surface of a document to acquire image data and a document type setting unit that receives input of setting of a document type of the document. A color-correction-constant changing unit changes a color correction constant to be used in an image processing based on the set document type. An image-data converting unit converts the image data to an image data in a first color space that is a common color space by applying the image processing based on the color correction constant to the image data.

### CROSS-REFERENCE TO RELATED APPLICATIONS

The present document incorporates by reference the entire contents of Japanese priority document, 2005-266015 filed in Japan on Sep. 13, 2005.

### BACKGROUND OF THE INVENTION

1. Field of the Invention

The present invention relates to an image processing apparatus such as a digital color multifunction product.

2. Description of the Related Art

Sometimes copying machines are connected to external terminals via a network, so that functions of the copying machines can be used by the terminals. For example, a function of distributing image data (for example, image data read from a document by a scanner) input to a digital color multifunction product to other terminals, such as a computer connected to the multifunction product, via a network has been proposed, and this kind of function is gradually in use.

In distributing scanned image data, if the distribution function described above is used, various processing conditions are set by the multifunction product or by a computer terminal; which is a destination of the distribution. A scanner is operated according to the set processing conditions, and the read document image data is subjected to a predetermined process such as conversion, and transferred to the distribution destination.

Japanese Patent Application Laid-Open (JP-A) No. 2000-333026 describes a conventional example of image reading and image processing to be performed according to setting of processing conditions, when a distribution and scanner function is used.

JP-A No. 2000-333026 proposes a system in an image forming apparatus such as a copying machine, in which an expansion box based on the architecture of a general computer system is equipped as a print server or a server of scanned images, for function enhancement. It is described in JP-A No. 2000-333026 that the scanned image is stored in a hard disk device in the expansion box, the image files stored therein are shared by computer systems connected via the network, and utilization thereof can be realized by respective server functions.

Furthermore, JP-A No. 2000-333026 describes processing of scanned images when a scan box function (one of functions for distributing a scanned image to a client computer) is used. Reading of documents and processing of scanned document images are performed according to processing conditions set by input of operations. However, because the scan box function is used when print output is not always expected, a Yellow-Magenta-Cyan-Black (YMCK) data format required for print output is not generated, that is, color coordinate transformation of the scanned image from an Red-Green-Blue (RGB) system to a YMCK system, tone correction, compression of image data, and the like are omitted, and RGB data after the scanned image is processed is stored in the scan box. Thereafter, the client computer in the network extracts the image data as the stored RGB data as it is, and transfers the image data to a local disk or the like, which is a storage held by the client computer itself. The client computer can browse the scanned image on a monitor display based on the transferred RGB data.

Thus, in the conventional distribution and scanner function, as disclosed in JP-A No. 2000-333026, image data is stored in a hard disk as the RGB data of the scanned image on the assumption that the computer terminal at the distribution destination uses the image data in the RGB data format, and it is not intended to convert an image format of the stored data at the time of distributing the stored data. Therefore, even if a client requests distribution of the stored data under a condition of a different image format, the format of the stored data cannot be converted, and the request of the client cannot be realized as a result. When the image processing apparatus including the distribution function is an apparatus including an image forming unit such as a copying machine, there is an advantage that the productivity of image formation can be increased by storing the input image in an exclusive data format convenient for image formation, at the time of storing the input image. However, in the RGB data format as in JP-A No. 2000-333026, this advantage cannot be utilized.

Therefore, in recent years, a function of converting RGB image data stored in the scan box to Cyan-Magenta-Yellow-Black (CMYK) data and distributing the image data to an apparatus having the image forming unit such as the copying machine has been desired.

Japanese Patent Nos. 2602681 and 2627753 propose a color image processing apparatus (a color image processing method) that converts RGB data to CMYK data.

However, when a document is read by a reading unit such as a digital color multifunction product, there is a problem that, even when the type of document (used coloring material) is different, they appear to be the same color under a particular light source. This problem is referred to as “metamerism”. On the other hand, there is another problem that, even when documents appear to be the same color to human eyes, a read value by the reading unit can be different due to a difference of the coloring material of the documents.

### SUMMARY OF THE INVENTION

It is an object of the present invention to at least partially solve the problems in the conventional technology.

According to an aspect of the present invention, an image processing apparatus includes an image reading unit that reads an image of a surface of a document to acquire image data; a first image-data converting unit that converts the image data to first image data in a first color space that is a common color space by applying a first image processing based on a first color correction constant to the image data; a storage unit that stores therein the first image data; a second image-data converting unit that converts the first image data present in the storage unit to second image data in a second color space corresponding to an output destination of the read image by applying a second image processing based on a second color correction constant; a document type setting unit that receives input of setting of a document type of the document; and a first color-correction-constant changing unit that changes the first color correction constant to be used in the first image processing based on the document type set by the document type setting unit.

According to another aspect of the present invention, an image processing apparatus includes an image reading unit that reads an image of a surface of a document to acquire image data; a document type setting unit that receives input of setting of a document type of the document; a color-correction-constant setting unit sets a color correction constant in accordance with set document type; and an image-data converting unit converts the image data to an image data in a common color space by applying an image processing based on set color correction constant to the image data.

According to still another aspect of the present invention, an image processing method includes reading an image of a surface of a document to acquire image data; setting a document type of the document; setting a color correction constant in accordance with set document type; and converting the image data to an image data in a common color space by applying an image processing based on set color correction constant to the image data.

The above and other objects, features, advantages and technical and industrial significance of this invention will be better understood by reading the following detailed description of presently preferred embodiments of the invention, when considered in connection with the accompanying drawings:

### BRIEF DESCRIPTION OF THE DRAWINGS

FIG. 1 is a schematic for explaining a system configuration of a digital color multifunction product according to an embodiment of the present invention and flow of image data at the time of copying in the digital color multifunction product;

FIG. 2 is a process block diagram of the configuration of a scanner correction unit shown in FIG. 1;

FIG. 3 is a plan view of an operation panel shown in FIG. 1;

FIG. 4 is a process block diagram of the configuration of a first image-correcting unit shown in FIG. 1;

FIG. 5 is a schematic for explaining flow of image data at the time of data distribution in the digital color multifunction product shown in FIG. 1;

FIG. 6 is a process block diagram of the configuration of a second image-correcting unit shown in FIG. 1 or 5; and

FIG. 7 is another plan view of the operation panel shown in FIG. 1 or 5.

### DETAILED DESCRIPTION OF THE PREFERRED EMBODIMENTS

Exemplary embodiments according to the present invention will be explained below in detail with reference to the accompanying drawings.

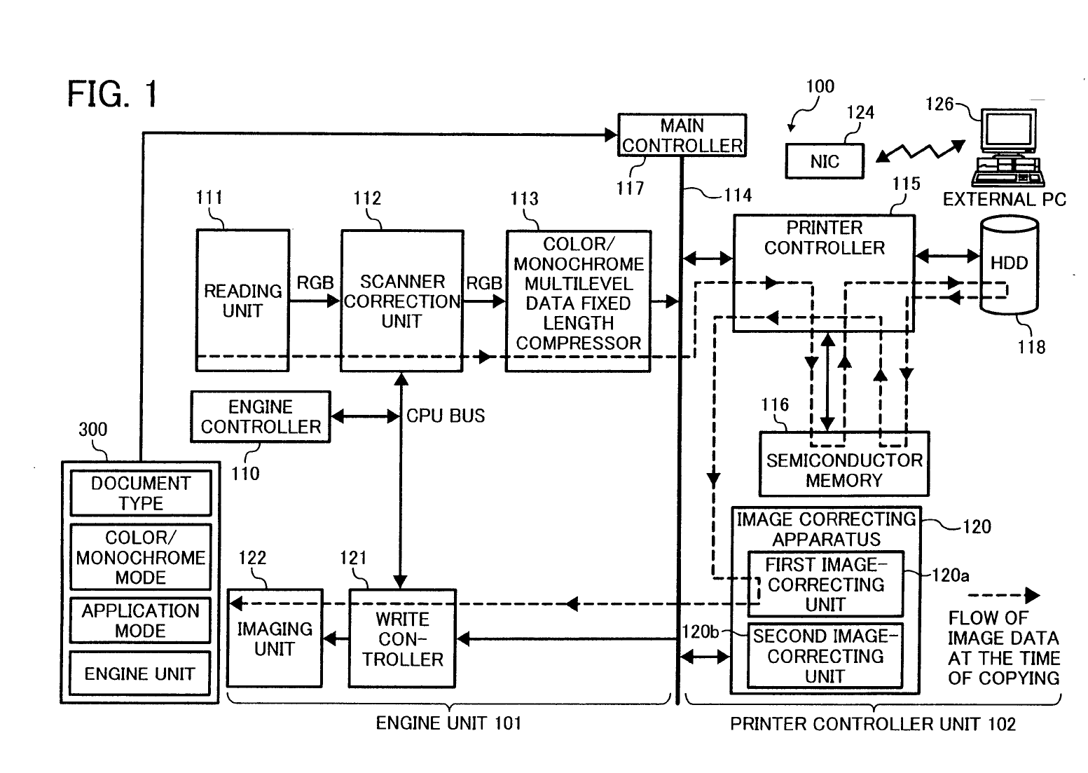

An embodiment of the present invention is explained with reference to FIGS. 1 to 7. This embodiment explains an example of an image processing apparatus, namely, a digital color multifunction product that combines a copy function, a facsimile (FAX) function, a printer function, and a function of distributing an input image (a read document image or an image input by the printer or the FAX function).

FIG. 1 is a schematic for explaining a system configuration of a digital color multifunction product 100 according to an embodiment of the present invention and flow of image data at the time of copying in the digital color multifunction product. The digital color multifunction product 100 includes a main controller 117 having a microcomputer configuration that controls the entire digital color multifunction product 100. The digital color multifunction product 100 includes an engine unit 101 and a printer controller unit 102.

An operation of respective parts of the digital color multifunction product 100 is explained along with the explanation of flow of image data at the time of copying in the digital color multifunction product 100.

The engine unit 101 includes an engine controller 110 that controls the engine unit 101. The engine unit 101 includes a reading unit 111, which is an image reader, that reads an image of a document. The reading unit 111 reads the document image as image data color-separated to R, G, and B, and transmits the read data to a scanner correction unit 112, which is a first image data converter. The scanner correction unit 112 converts the color from an RGB signal peculiar to the device read by the reading unit 111 to an RGB signal common to a plurality of devices on a color space. Color conversion to the common color space is performed to reuse the image data.

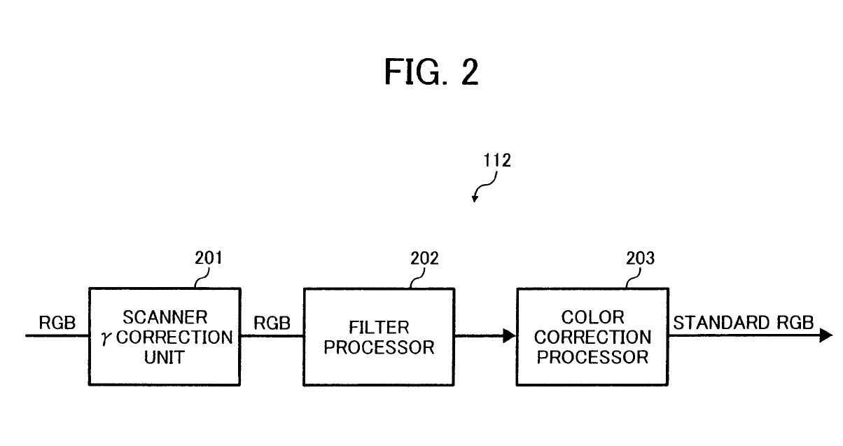

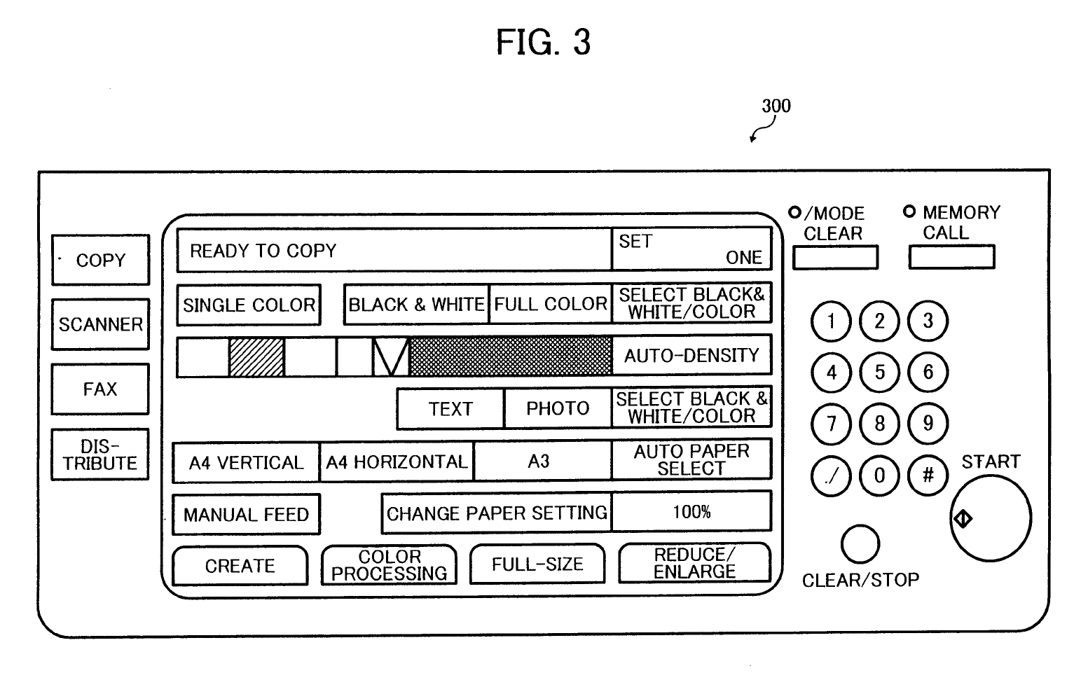

As shown in FIG. 2, the scanner correction unit 112 includes a scanner γ-correction unit 201, a filter processor 202, and a color correction processor 203. The scanner γ-correction unit 201 performs a scanner γ-correction process, the filter processor 202 performs a filtering process, and the color correction processor 203 performs a color correction process with respect to the RGB image data. More specifically, the scanner γ-correction unit 201 includes a look up table (LUT) having 8 bits for input, and 8 bits for output for each channel of RGB. The filter processor 202 is a space filter processor by a matrix of about 5×5. The color correction processor 203 occasionally uses linear transformation by the matrix of 3×3 from input RGB to output RGB, and occasionally uses a three-dimensional LUT. A process mode selected by a user is reflected in these processes. The process mode is set by user input from, for example, an operation panel 300 provided outside of the body of the digital color multifunction product 100 as shown in FIG. 3, through a main controller 117. The process modes selectable by the user are a color/monochrome mode, an application mode, an image quality mode, and a document type mode. Specifically, the color/monochrome mode includes a full color mode, a single color mode, a monochrome mode or the like. The application mode includes a copy mode, a scanner mode, a FAX mode, a distribution mode or the like. The image quality mode includes a text mode, a text/photo mode, and a photo mode or the like. The document type mode includes a print document mode, a photographic paper document mode, an inkjet document mode or the like. Furthermore, notch information for deepening or lightening the color of the document is provided.

Respective 8-bit data having subjected to the processing in the scanner correction unit 112 is converted to n-bit (n≦8) data for each color by a color/monochrome multilevel data fixed length compressor 113. The compressed image data is transmitted to a printer controller 115 in the printer controller unit 102 via a general-purpose bus 114.

The printer controller 115 includes a semiconductor memory 116 for storing image data. The semiconductor memory 116 stores the transmitted image data under control of the main controller 117. The image data (image data in a first color space) stored in the semiconductor memory 116 and information of the process mode input from the operation panel 300 are stored in a hard disk drive (HDD) 118, which works as a storage unit. This configuration is for avoiding the document being reread even when paper jam has occurred at the time of printout by the digital color multifunction product 100 and printing has not finished normally, and for performing electronic sorting. Recently, a function for storing a read document and outputting the document again as required is also added. That is, the image data is once developed in the semiconductor memory 116, and stored in the hard disk 118.

When the image data is output, the image data stored in the hard disk 118 as the storage unit is once developed in the semiconductor memory 116 of the printer controller 115, converted to 8-bit RGB image data for each color by the printer controller 115, and transmitted to an image correcting apparatus 120, which is a second image data converter, via the general-purpose bus 114. It is because the write speed and the read speed of the hard disk 118 is not constant and irregular that the image data stored in the hard disk 118 is once developed in the semiconductor memory 116 before being output to the engine unit 101.

The image correcting apparatus 120 includes a first image-correcting unit 120a and a second image-correcting unit 120b by a corresponding application (a printer application for outputting image data on paper, and a distribution application for distributing image data).

The RGB image data (image data in the first color space) read from the hard disk 118 is converted to a CMYK color signal (image data in a second color space) corresponding to an imaging unit 122, which is an image output unit, by the first image-correcting unit 120a. This process is explained below in detail.

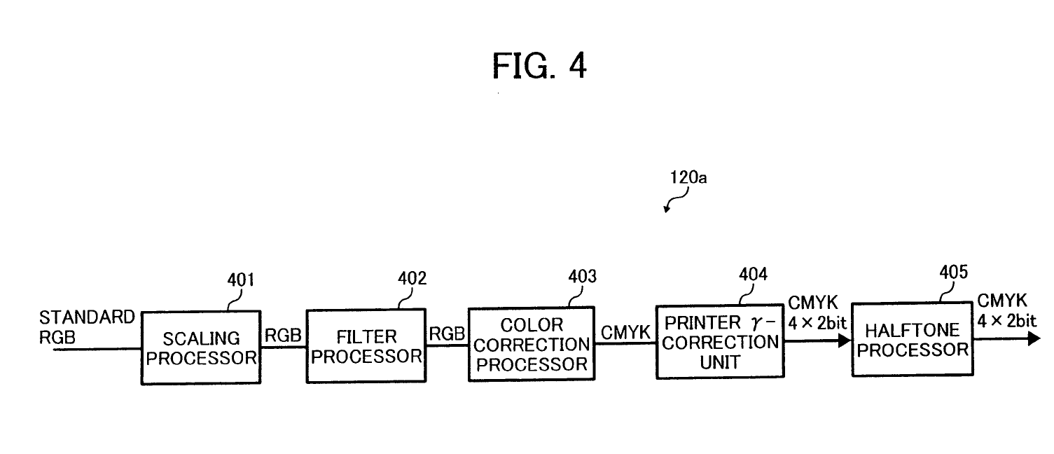

In the first image-correcting unit 120a, as shown in FIG. 4, a scaling processor 401 performs a scaling process, a filter processor 402 performs a filtering process, a color correction processor 403 performs a color correction process, a printer γ-correction unit 404 performs a printer γ-correction process, and a halftone processor 405 performs a halftone process, with respect to the 8-bit RGB image data of respective colors. More specifically, the scaling processor 401 performs a scaling process of an image according to a known cubic function convolution method. The filter processor 402 corrects blur of an image by using a space filter of about 5×5, or highlights the image according to the image quality mode. The color correction processor 403 converts the input RGB image data from a standard RGB color space to a color space matched with an output device, for example, to a CMYK color space. The printer γ-correction unit 404 performs a printer γ-correction process with respect to respective CMYK colors. The halftone processor 405 performs a halftone process (a process of converting the RGB color signal to a low-bit signal at the time of printing on paper, according to an error diffusion method or a dither method) matched with the write controller 121 and the imaging unit 122, transmits the image data to the subsequent stage as data to be used for imaging, and outputs the image data on transfer paper. A process mode selected by a user, that is, the process mode stored in the hard disk 118 is reflected in these processes.

As the printing method of the imaging unit 122, as well as an electrophotographic method, various methods such as an ink jet method, a sublimation dye transfer printing method, a silver salt photographic method, a direct thermosensitive recording method, and a thermofusible transfer method can be used.

A case that image data having subjected to image processing for copying and compressed in the RGB color space is stored in the hard disk 118 has been explained above. The image data stored in the hard disk 118 is image data in a certain color space read as a copy image by the digital color multifunction product 100. The certain color space can be a device dependent color space (Yuv, CMY) dependent on the type of device (device characteristic), or can be a device independent color space (sRGB) not dependent on the type of device (device characteristic). When a certain color space signal is transmitted to another apparatus via a network, the color space signal is corrected to the same color space that can be shared between the other apparatus. The certain color space is, for example, a standard RGB (sRGB) space, a Lab space, or a dedicated color space that can be shared among different devices.

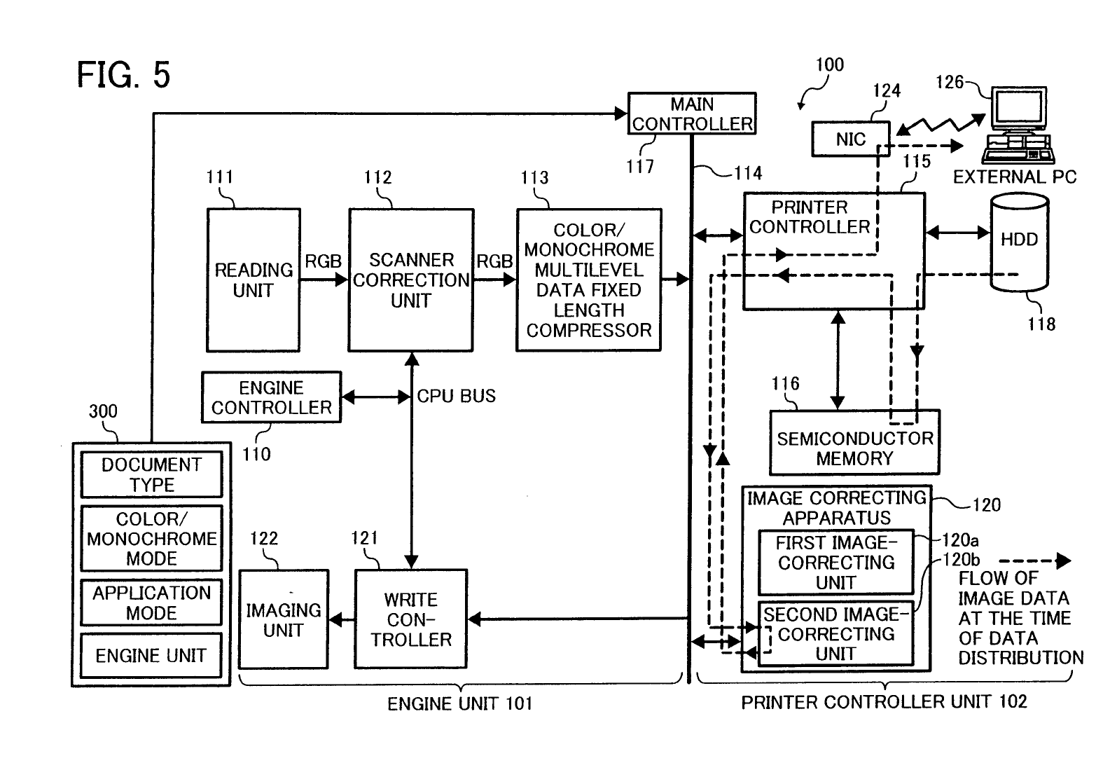

With reference to FIG. 5, the operation of respective units of the digital color multifunction product 100 is explained next, along a flow of the image data at the time of distributing data stored in the hard disk 118 to an external personal computer (PC) 126 via the network.

A network interface controller (NIC) 124 is an interface for connecting the digital color multifunction product 100 to the network such as a local area network (LAN) to which the external PC 126 is connected.

The RGB image data (image data in the first color space) having subjected to scanner correction, that is, image processing for copying, and the information of the process mode input from the operation panel 300 are stored in the hard disk 118. The process mode is set by user input from the operation panel 300, for example, provided outside of the body of the digital color multifunction product 100 as shown in FIG. 3. The process modes selectable by the user are a color/monochrome mode, an application mode, an image quality mode, and a document type mode. Specifically, the color/monochrome mode includes a full color mode, a single color mode, a monochrome mode or the like. The application mode includes a copy mode, a scanner mode, a FAX mode, a distribution mode or the like. The image quality mode includes a text mode, a text/photo mode, a photo mode or the like. The document type mode includes a print document mode, a photographic paper document mode, an inkjet document mode or the like. Furthermore, notch information for deepening or lightening the color of the document is provided.

The image data stored in the hard disk 118 is once developed in the semiconductor memory 116 of the printer controller 115, and then transmitted to the second image-correcting unit 120b via the general-purpose bus 114.

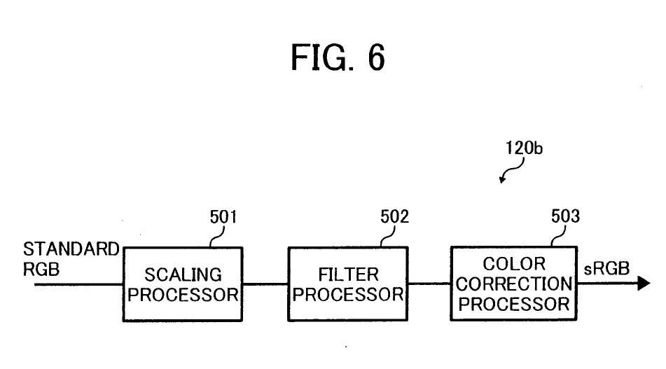

The second image-correcting unit 120b applies image processing suitable for the mode to the image based on the process mode. The second image-correcting unit 120b applies appropriate image format processing for distribution to the image and distributes the image to the external PC 126 via the NIC 124. For example, as shown in FIG. 6, in the second image-correcting unit 120b, a scaling processor 501 performs a scaling process, a filter processor 502 performs a space filtering process, and a color correction processor 503 performs a color correction process, with respect to the RGB image data. Specifically, the scaling processor 501 performs scaling of the image by the known cubic function convolution method. The filter processor 502 corrects blur and the like of the image by a space filter of approximately 5×5, or highlights the image according to the image quality mode. The color correction processor 503 converts the input RGB image data from a standard RGB color space to a color space matched with an output device, for example, to the sRGB color space. A process mode selected by a user, that is, the process mode stored in the hard disk 118 is reflected in these processes. The process mode of the desired image data can be specified also from the external PC 126 with respect to the digital color multifunction product 100. In this case, the main controller 117 detects the process mode transmitted from the external PC 126, transmits the process mode to the second image-correcting unit 120b, and the second image-correcting unit 120b converts the image data format so as to fit to the process mode desired by the external PC 126.

The second image-correcting unit 120b applies appropriate image format processing for distribution to the image data, and distributes the image data to the external PC via the NIC 124.

The main controller 117 is briefly explained next. The main controller 117 has a microcomputer configuration including a central processing unit (CPU) that controls the respective parts in a collective manner, a read only memory (ROM), which is a storage medium in which fixed data such as a start program executed by the CPU is written, and a random access memory (RAM) in which variable data such as work data is written in an updatable manner. The main controller 117 includes a nonvolatile ROM, and an application program executed by the CPU is stored in the nonvolatile ROM. In other words, when the user turns the power on, the CPU activates the start program in the ROM, the application program is read from the nonvolatile ROM to the RAM, thereby to start the application program. Accordingly, since the CPU operates according to the application program, the main controller 117 controls the entire operation of the digital color multifunction product 100. The application program can be fetched, for example, from the outside via the NIC 124, and can be installed in the nonvolatile ROM.

Among various functions of the digital color multifunction product 100, characteristic functions realized by the CPU in the main controller 117 that operates according to the application program are explained.

As described above, the digital color multifunction product 100 directly stores the scanned image as the RGB data in the hard disk 118, and converts the image format of the stored data at the time of printing or distributing the stored data.

At the time of reading the document by the reading unit 111, there is a problem of metamerism such that even when the type of document (used coloring material) is different, they appear to be the same color under a particular light source. On the other hand, even if documents appear to be the same color to human eyes, a read value by the reading unit 111 can be different due to a difference of the coloring material of the documents.

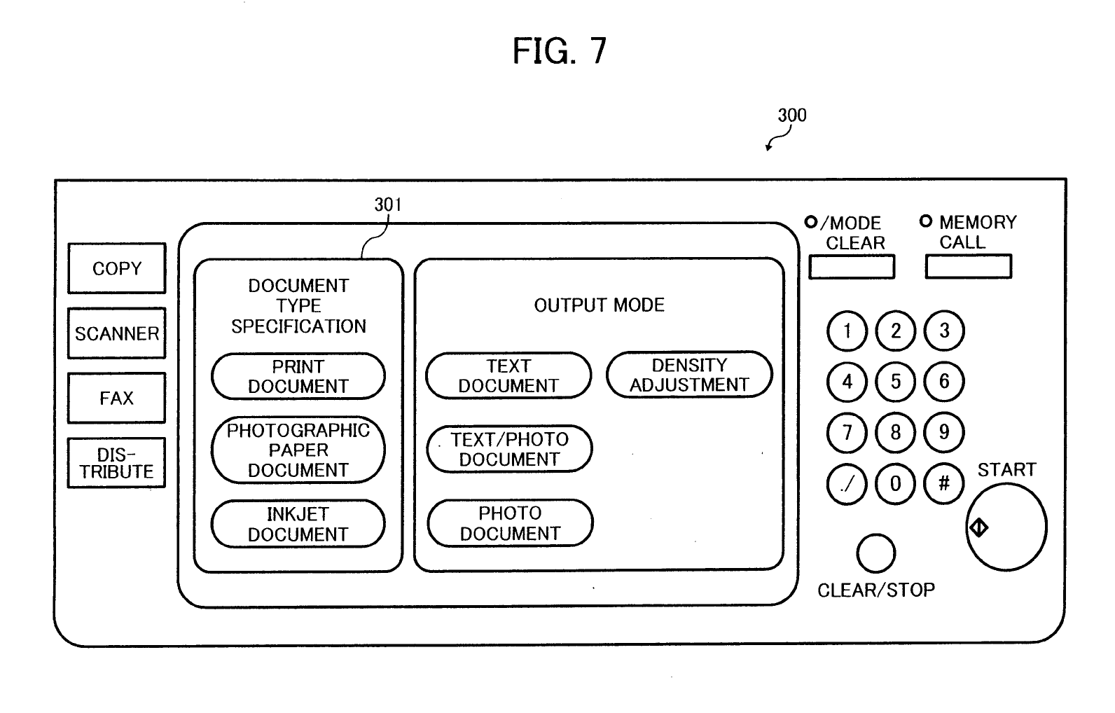

In the digital color multifunction product 100 according to the present embodiment, therefore, a constant for color correction is changed over according to the type of the document, such as print document, photographic paper document, and inkjet document, to absorb the metamerism, thereby handling this problem. More specifically, a document type specifying key 301 for specifying the document type such as print document, photographic paper document, and inkjet document is displayed on the operation panel 300 provided outside of the body of the digital color multifunction product 100, for example, as shown in FIG. 7, so that the user specifies the document type such as print document, photographic paper document, and inkjet document, at the time of storing the image via the main controller 117. A document type setting unit is realized accordingly.

The document type specified in this manner is transmitted to the scanner correction unit 112 and the image correcting apparatus 120 (the first image-correcting unit 120a and the second image-correcting unit 120b) via the main controller 117, and stored in the hard disk 118 corresponding to the image data input from the reading unit 111.

A changeover process of the color correction constant (a first color correction constant-changing unit) according to the document type, executed with respect to the scanner correction unit 112 by the CPU in the main controller 117 that operates according to the application program, is explained below.

The scanner γ-correction unit 201 can absorb the hue of the document type (the used coloring material) by correcting a difference in gray balance due to a difference in the document type (the used coloring material). However, the document cannot be matched with the stored image with regard to all colors. Therefore, in the present embodiment, the hue is corrected by changing a color conversion parameter according to the setting of the document type by the color correction processor 203 after the scanner γ-correction. As a result, the visual color of the document can be matched with the color of the stored image data. Furthermore, when the image data stored in the hard disk 118 is used by a plurality of applications, or transferred to another apparatus and used, excellent color reproducibility can be obtained without changing the color conversion parameters of the color correction processors 403 and 503 in the image correcting apparatus 120 according to the document type.

In addition, in the present embodiment, a filter parameter of the filter processor 202 is changed according to the setting of the document type. The reason for changing the filter parameter of the filter processor 202 according to the setting of the document type is described below. That is, the print document is formed of halftone dots. The inkjet document is formed of a processing pattern of the printer used for output (dither or error diffusion). On the other hand, the photographic paper document is formed of continuous tones. Therefore, when the input image has a pattern like the print document and the inkjet document, accurate color conversion can be performed by smoothing the halftone dots and the pattern by a smoothing filter. As a result, the visual color and the color of the stored image data are matched-with each other regardless of the document type. When the image data stored in the hard disk 118 is reused, excellent resolution can be obtained without changing the filter parameters of the filter processors 402 and 502 in the image correcting apparatus 120.

Basically, the image data is converted to common image data at the time of being stored in the hard disk 118, taking reusability into consideration. However, according to the type of the stored document, it can be desired to change the color correction constant in the image correcting apparatus 120 (the first image-correcting unit 120a and the second image-correcting unit 120b). In this case, the document type information stored in the hard disk 118 corresponding to the image data is read by the main controller 117, appropriate setting is performed with respect to the image correcting apparatus 120 (the first image-correcting unit 120a and the second image-correcting unit 120b), and a process corresponding to the document type is performed (a second color correction constant-changing unit).

Firstly, the color conversion parameters of the color correction processors 403 and 503 in the image correcting apparatus 120 are changed over based on the document type information. That is, the document type information stored in the hard disk 118 corresponding to the image data is read by the main controller 117, and the parameters of the color correction processors 403 and 503 are changed based on the information. This is because the print documents are mainly office documents, and hence clearer color reproduction is required, whereas since the photographic paper document is a photographic image, color reproduction of the document with fidelity is required. Accordingly, the image data can be changed to optimum hue according to the document type.

Secondly, the filter parameters of the filter processors 402 and 502 in the image correcting apparatus 120 are changed over based on the document type information. That is, the document type information stored in the hard disk 118 corresponding to the image data is read by the main controller 117, and the parameters of the parameters of the filter processors 402 and 502 are changed based on the information. The reason for changing the filter parameters of the filter processors 402 and 502 based on the document type information is described below.

When the image stored in the hard disk 118 is an image of photographic paper, since the original image does not have a halftone dot structure, the halftone dot structure is not found in the stored image. When the image stored in the hard disk 118 is an image of a print document, the original image has the halftone dot structure. Therefore, components of halftone dots can be slightly left in the stored image. If the same processing is performed for the both cases in the filter processors 402 and 502, moire can be generated in the case of the print document, or the resolution can be insufficient in the case of a photographic paper document. In other words, an output image corresponding to the document type can be obtained by performing an appropriate process in the filter processors 402 and 502, based on detection as to whether the stored image is photographic paper. Accordingly, a balance between the resolution of the image and moire can be appropriately changed.

Thirdly, a halftone processing parameter and a halftone processing method of the halftone processor 405 in the image correcting apparatus 120 are changed over based on the document type information. That is, the document type information stored in the hard disk 118 corresponding to the image data is read by the main controller 117, and the halftone processing parameter and the halftone processing method of the halftone processor 405 are changed based on the information. The reason for changing the halftone processing parameter and the halftone processing method of the halftone processor 405 according to the document type information is described below.

That is, when the image stored in the hard disk 118 is wan image of photographic paper, since the original image does not have a halftone dot structure, the halftone dot structure is not seen in the stored image. When the image stored in the hard disk 118 is an image of a print document, the original image has the halftone dot structure. Therefore, components of halftone dots can be slightly left in the stored image. In other words, it is desired to perform error diffusion processing having no periodicity as the halftone processing method with respect to the print document. On the other hand, with respect to the photographic paper document, moire is not generated even if the dither processing having the periodicity is performed, and smooth tone reproduction can be made. Accordingly, a balance between smoothness and moire can be appropriately changed over according to the document type.

Thus, according to the present embodiment, by changing the color correction constant in the scanner correction unit 112 according to the set document type, documents visually identical to human eyes can be corrected to the image data in the first color space, which is the common color space having the same hue, thereby enabling handling of the problem of metamerism. Furthermore, when the image data in the first color space stored in the hard disk 118 is reused in a plurality of applications, or transferred to another apparatus and used, the image data in the first color space stored in the hard disk 118 can be reused without performing correction based on the document by the image correcting apparatus 120. Accordingly, a high quality process can be performed without requiring information other than the image data.

According to one aspect of the present invention, by performing a changing process of the color correction constant in the first image data converter according to the document type set by the document type setting unit, documents visually identical to human eyes can be corrected to the image data in the first color space, which is the common color space having the same hue, thereby enabling handling of the problem of metamerism. Furthermore, when the image data in the first color space stored in the storage unit is reused in a plurality of applications or transferred to another apparatus and used, the image data in the first color space stored in the storage unit can be reused without performing correction based on the document by the second image data converter. Accordingly, a high quality process can be performed without requiring information other than the image data.

According to another aspect of the present invention, by changing the color conversion parameter relating to a color correction process performed by the first image data converter according to the document type set by the document type setting unit, the visual color of the document can be matched with the color of the image data in the first color space stored in the storage unit. Furthermore, when the image data in the first color space stored in the storage unit is used by a plurality of applications, or transferred to another apparatus and used, excellent color reproducibility can be obtained without changing the color conversion parameter of the second image data converter according to the document type.

According to still another aspect of the present invention, by changing the filter parameter relating to a filtering process performed by the first image data converter according to the document type set by the document type setting unit, halftone dots are smoothed with respect to a print document formed of halftone dots. Thus, color conversion can be performed accurately with respect to a print document having a halftone dot structure and a photographic paper document having no halftone dot structure. As a result, a visual color and the color of the stored image data can be matched with each other. Furthermore, when the image data in the first color space stored in the storage unit is used by a plurality of applications, or transferred to another apparatus and used, excellent resolution can be obtained without changing the filter parameter of the second image data converter according to the document type.

According to still another aspect of the present invention, the document type set by the document type setting unit is stored in the storage unit, corresponding to the image data in the first color space converted by the first image data converter by performing a changing process of the color correction constant according to the document type. Therefore, for example, when it is desired to change a finished state according to the photographic paper document or the print document, an appropriate process can be performed according to the document type stored in the storage unit corresponding to the image data in the first color space.

According to still another aspect of the present invention, for example, when it is desired to change a finished state according to the photographic paper document or the print document, the image data can be corrected to image data in the second color space according to the document type, by performing a changing process of the color correction constant in the second image data converter according to the document type stored in the storage unit corresponding to the image data in the first color space.

According to still another aspect of the present invention, by changing the color conversion parameter relating to a color correction process performed by the second image data converter according to the document type, the image data can be changed to an optimum hue according to the document type.

According to still another aspect of the present invention, by changing the filter parameter relating to a filtering process performed by the second image data converter according to the document type, a balance between the resolution of the image and moire can be appropriately changed.

According to still another aspect of the present invention, by changing the halftone processing parameter or the halftone processing method relating to a halftone process performed by the second image data converter according to the document type, a balance between the smoothness and moire can be appropriately changed.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An image processing apparatus comprising:
an image reading unit that reads an image of a surface of a document to acquire image data;
a first image-data converting unit that converts the image data to first image data in a first color space that is a common color space by applying a first image processing based on a first color correction constant to the image data;
a storage unit that stores therein the first image data;
a second image-data converting unit that converts the first image data present in the storage unit to second image data in a second color space corresponding to an output destination of the read image by applying a second image processing based on a second color correction constant;
a document type setting unit that receives input of setting of a document type of the document; and
a first color-correction-constant changing unit that changes the first color correction constant to be used in the first image processing based on the document type set by the document type setting unit.

2. The image processing apparatus according to claim 1, wherein the first image processing is color correction, and the first color-correction-constant changing unit changes a color conversion parameter used in the color correction.

3. The image processing apparatus according to claim 1, wherein the first image processing is filtering, and the first color-correction-constant changing unit changes a filter parameter used in the filtering.

4. The image processing apparatus according to claim 1, wherein the storage unit stores therein the document type in association with the first-image data.

5. The image processing apparatus according to claim 4, further comprising a second color-correction-constant changing unit that changes the second color correction constant to be used in the second image processing based on the document type present in the storage unit corresponding to the first image data.

6. The image processing apparatus according to claim 5, wherein the second image processing is color correction, and the second color-correction-constant changing unit changes a color conversion parameter used in the color correction.

7. The image processing apparatus according to claim 5, wherein the second image processing is filtering, and the second color-correction-constant changing unit changes a filter parameter used in the filtering.

8. The image processing apparatus according to claim 5, wherein the second image processing is halftone processing, and the second color-correction-constant changing unit changes any one of a halftone processing parameter and a halftone processing method used in the halftone processing.

9. An image processing apparatus comprising:
an image reading unit that reads an image of a surface of a document to acquire image data;
a document type setting unit that receives input of setting of a document type of the document;
a color-correction-constant setting unit sets a color correction constant in accordance with set document type; and
an image-data converting unit converts the image data to an image data in a common color space by applying an image processing based on set color correction constant to the image data.

10. An image processing method comprising:
reading an image of a surface of a document to acquire image data;
setting a document type of the document;
setting a color correction constant in accordance with set document type; and
converting the image data to an image data in a common color space by applying an image processing based on set color correction constant to the image data.
